(19) United States
(12) Patent Application Publication
(10) Pub. No.: US 2026/0135534 A1
(43) Pub. Date: May 14, 2026

(54) RECEIVER CHAIN WITH DYNAMIC GAIN SLOPE EQUALIZER

(71) Applicant: Qorvo US, Inc., Greensboro, NC (US)

(72) Inventor: Outmane Lemtiri Chlieh, Lowell, MA (US)

(21) Appl. No.: 19/121,063

(22) PCT Filed: Oct. 24, 2023
(86) PCT No.: PCT/US2023/035775

§ 371 Date: Apr. 14, 2025

Related U.S. Application Data
(60) Provisional application No. 63/383,762, filed on Nov. 15, 2022.

(51) Int. Cl. H03G 5/16; H03F 1/26

(52) U.S. Cl. CPC H03G 5/165; H03F 1/26; H03F 2200/294; H03G 2201/103; H03G 2201/307

(57) ABSTRACT

A receiver chain with a dynamic gain slope equalizer is disclosed. In one aspect, the receiver chain may operate in a first mode where a single low noise amplifier (LNA) is used (e.g., a low-gain mode) and a second mode where multiple LNAs are used (e.g., a high-gain mode). An equalizer that may dynamically adjust a gain slope based on mode may be positioned serially between the LNAs. As LNAs are switched in and out based on mode changes, the equalizer may switch in and out capacitors in resonant circuits and resistors in a resistive network.

### PRIORITY CLAIM

The present application claims priority to U.S. Provisional Patent Application Ser. No. 63/383,762 filed on Nov. 15, 2022, and entitled “RECEIVER CHAIN WITH DYNAMIC GAIN SLOPE EQUALIZER,” the contents of which are incorporated herein by reference in its entirety.

### BACKGROUND

### I. Field of the Disclosure

The technology of the disclosure relates generally to receiver chains and, more particularly, to receiver chains that may switch between different modes such as a high-gain mode and a low-gain mode.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to increase bandwidth available to send and receive signals to and from such devices. The evolving cellular standards, as well as other wireless standards have, in many cases, adopted multiple input multiple output (MIMO) antenna arrays to assist in handling the increasingly sophisticated signaling schemes. The evolution of MIMO antenna arrays provides opportunities for innovation.

### SUMMARY

Aspects disclosed in the detailed description include a receiver chain with a dynamic gain slope equalizer. In particular, the receiver chain may operate in a first mode where a single low noise amplifier (LNA) is used (e.g., a low-gain mode) and a second mode where multiple LNAs are used (e.g., a high-gain mode). An equalizer that may dynamically adjust a gain slope based on mode may be positioned serially between the LNAs. As LNAs are switched in and out based on mode changes, the equalizer may switch in and out capacitors in resonant circuits and resistors in a resistive network to provide a desired gain slope to meet flatness specifications provided by customers.

In this regard in one aspect, a receiver chain is disclosed. The receiver chain comprises a first amplifier. The receiver chain also comprises a second amplifier switchably connected in series with the first amplifier. The receiver chain also comprises a reconfigurable gain equalizer serially positioned between the first amplifier and the second amplifier.

In another aspect, a method for providing equalization in a receiver chain is disclosed. The method includes using a switch to place a first amplifier in series with a second amplifier and while the second amplifier is in series with the first amplifier, applying a first equalization with a reconfigurable gain equalizer. The method also includes using the switch to switch the second amplifier out of series with the first amplifier and while the second amplifier is not in series with the first amplifier, applying a second equalization with the reconfigurable gain equalizer.

In another aspect, a wireless computing device is disclosed. The wireless computing device includes a transceiver comprising a receiver chain comprising a first amplifier and a second amplifier switchably connected in series with the first amplifier and further comprising a reconfigurable gain equalizer serially positioned between the first amplifier and the second amplifier.

### BRIEF DESCRIPTION OF THE DRAWINGS

FIG. 1 is a block diagram of an exemplary receiver chain in a transceiver circuit that may implement aspects of the present disclosure;

FIG. 2 is a more detailed diagram of the receiver chain of FIG. 1 showing the dynamic equalizer of the present disclosure serially positioned between two low noise amplifiers (LNAs);

FIG. 3 is a circuit diagram of an exemplary dynamic equalizer according to an exemplary aspect of the present disclosure; and

FIG. 4 is a block diagram of a mobile terminal, which may include the receiver chain having the dynamic equalizer of FIGS. 2 and 3 according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element, or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include a receiver chain with a dynamic gain slope equalizer. In particular, the receiver chain may operate in a first mode where a single low noise amplifier (LNA) is used (e.g., a low-gain mode) and a second mode where multiple LNAs are used (e.g., a high-gain mode). An equalizer that may dynamically adjust a gain slope based on mode may be positioned serially between the LNAs. As LNAs are switched in and out based on mode changes, the equalizer may switch in and out capacitors in resonant circuits and resistors in a resistive network to provide a desired gain slope to meet the flatness specifications provided by customers.

Transceiver architecture, and particularly transceivers having receivers having massive multiple input-multiple output (MIMO) antenna arrays, generally require LNAs with switches that switch between transmit modes and receive modes. Historically, such a structure might have a mixed technology solution on a single laminate. For example, the LNAs could be a bipolar technology (e.g., transistors and the like made from gallium arsenide (GaAs)) and the switches could be silicon on insulator (SOI) technology. Such a hybrid approach may be chosen because GaAs provides higher gain and bandwidth with lower noise figure (NF) and an overall higher output third-order intermodulation product (OIP3). SOI technology has a better figure of merit for radio frequency (RF) switches and is better suited for control or bias signal generation. In general, SOI technology is also cheaper than GaAs.

Recent trends suggest that an all-SOI approach may be required to reduce package footprint and control costs. Putting the LNAs in SOI creates challenges in meeting the general flatness requirements. That is, a single-stage cascode amplifier that has a good return loss (RL) and NF in band without any frequency-dependent feedback will have a gain profile that has a negative slope. This negative slope is undesirable and may be corrected to meet customer specifications. When there are multiple LNA stages, this slope may double, making compensation more challenging.

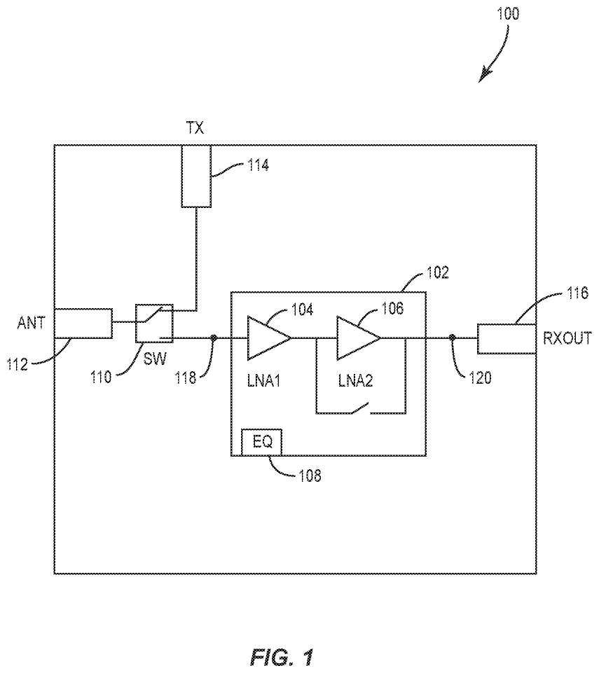

Exemplary aspects of the present disclosure provide a solution to this negative slope by providing a dynamic equalizer that may adjust a gain slope of the full receiver dynamically based on a mode of operation of a receiver chain. In this regard, FIG. 1 is a block diagram of a transceiver chip 100 having a receiver chain 102 with a first LNA 104 and a second LNA 106 serially coupled to the first LNA 104, although it should be appreciated that the first LNA 104 and the second LNA 106 could be other types of amplifiers and may be generically referred to as amplifiers. A dynamic equalizer 108 interoperates with the LNAs 104, 106. While referred to herein as a dynamic equalizer, it should be appreciated that the dynamics are not continuous in nature and rather reflect different operational states, and as such, the dynamic equalizer 108 may equivalently be referred to as a reconfigurable gain equalizer that is configured to provide a first attenuation slope correction in a first mode and a second attenuation slope correction in a second mode. The receiver chain 102 is coupled to a switch 110 that selectively couples the receiver chain 102 to an antenna port 112. Alternatively, the switch 110 may couple a transmitter port 114 to the antenna port 112. The receiver chain 102 is further coupled to an output port 116.

When receiving a signal at an antenna (not shown), an RF signal is provided from the antenna to the antenna port 112. An input node 118 is coupled to the first LNA 104 of the receiver chain 102 and may be considered an RF input node that is configured to be coupled to an antenna path. Likewise, an output node 120 is coupled to the second LNA 106 and may be considered an RF output node. The transceiver chip 100 may be an SOI chip.

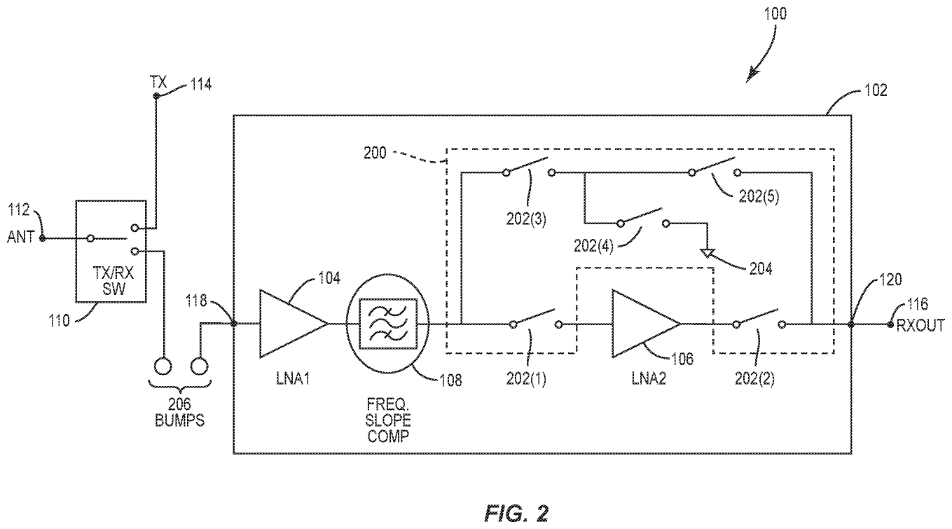

More detail is provided in FIG. 2. The switch 110 may be a single pole, double throw (SPDT) switch. The dynamic equalizer 108 is serially positioned between the LNA 104 and the LNA 106. The LNA 106 has a bypass circuit 200 with a plurality of switches 202(1)-202(5). The plurality of switches 202(1)-202(5) selectively creates a short circuit bypass around the LNA 106 in a first mode and creates an open circuit in a second mode such that the second LNA 106 is serially coupled to the first LNA 104.

More specifically, in a first high-gain mode, switches 202(1) and 202(2) are closed such that the LNA 106 is active in the receiver chain 102 between the nodes 118, 120. In this first high-gain mode, switches 202(3) and 202(5) are open. Further, the switch 202(4) is also closed to short to ground 204 the path between the switches 202(3) and 202(5). In a second low-gain mode, the switches 202(3) and 202(5) are closed, creating a short circuit that causes signals in the receiver chain 102 to bypass the LNA 106. In this second, low-gain mode, switches 202(1), 202(2) and 202(4) are open.

While in some aspects, the antenna path is the path from the antenna to the antenna port 112, through the switch 110, to the LNA 104, the dynamic equalizer 108, and the LNA 106 to the output port 116, there are situations where the antenna path may include external circuitry that is outside the transceiver chip 100. For such situations, the transceiver chip 100 may include contact bumps 206 that allow connection to such external circuitry for off-chip RF matching, for example, or the like. If such external circuitry is not needed, a short circuit may be established across the contact bumps 206 to maintain the antenna path.

Note also that there may be situations where, for design criteria, the switches 202(1)-202(5) may be moved off chip, and appropriate interconnections or bumps analogous to bumps 206 may be provided. Likewise, there may be other switching arrangements that may be used while still making the LNA 106 switchably connected in series with the LNA 104.

The dynamic equalizer 108 compensates for not only the negative slope of the receiver chain 102 but effectively the entire transceiver chip 100. Note that the dynamic equalizer 108 may compensate for a steeper slope in a high-gain mode compared to a low-gain mode and is, accordingly, dynamic to allow for such changes in compensation. In general, the dynamic equalizer 108 may treat attenuation within the transceiver chip 100 generally and specifically within the receiver chain 102 as coming from two terms: first, fixed attenuation across frequency, but that changes with a mode of operation change; and second, variable attenuation as a function of frequency and mode. This may be expressed mathematically as follows:

$$ATT ( freq , mode ) = {ATT}_{1} ( mode ) + {ATT}_{2} ( freq , mode ) \qquad Equation 1$$

The dynamic equalizer 108 may address both terms of Equation 1. More specifically, the first term may be addressed with a digital step attenuator, and the second term may be addressed with resonators. The digital step attenuator, with its weak dependency on frequency, is used to provide the bulk of the attenuation needed over the whole frequency band of interest. Concurrently, the resonators provide attenuation for in-band peaking.

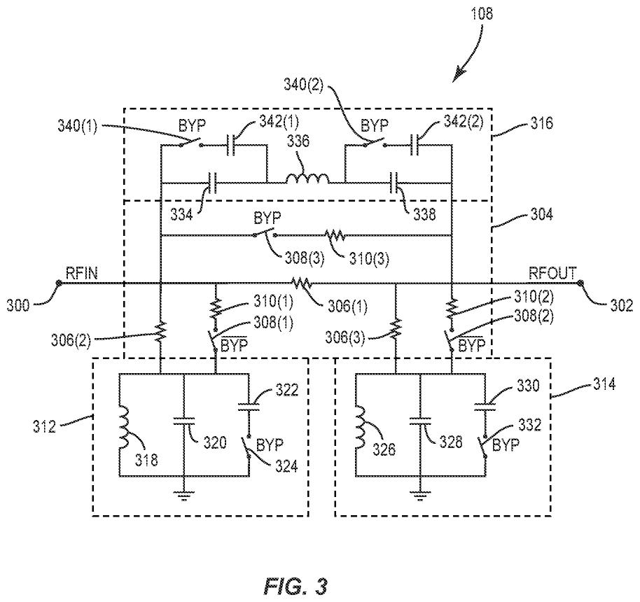

FIG. 3 shows an exemplary circuit diagram for the dynamic equalizer 108. The dynamic equalizer 108 may include an input port 300, which may be an RF input port, and an output port 302, which may be an RF output port. The dynamic equalizer 108 may include a digital step attenuator 304, which is a II-resistive network. Specifically, the II-resistive network has a core II shape formed by resistors 306(1)-306(3).

The resistor 306(1) is positioned serially between the input port 300 and the output port 302. Leg resistors 306(2), 306(3) are positioned on either side of the resistor 306(1). In a high-gain mode (i.e., both LNAs 104, 106 are being used), switches 308(1), 308(2) are closed, adding leg resistors 310(1), 310(2) to the II-shape. Leg resistor 310(1) is electrically parallel to the leg resistor 306(2), and leg resistor 310(2) is electrically parallel to the leg resistor 306(3). In this mode, a third switch 308(3), is open.

In contrast, in a low-gain mode, the third switch 308(3) is closed, adding resistor 310(3) in parallel to the resistor 306(1). In this low-gain mode, the switches 308(1), 308(2) are open. The values of the resistors 306(1)-306(3), 310(1)-310(3) may be selected to give the desired static attenuation over all the frequency bands of interest.

As noted, the second term of Equation 1 may be provided by resonators. Specifically, an input shunt resonator 312, an output shunt resonator 314, and a series resonator 316 may be provided. The resonators 312, 314, 316 are LC circuits and more specifically LC resonators formed by inductors and capacitors as explained in greater detail below. The different modes of operation are enabled by switches adding in or taking out capacitors. This choice is primarily based on size in that inductors are much larger than capacitors, so it is easier to add capacitors to a chip than it is to add inductors. However, it should be appreciated that different resonators that add or subtract inductors could also be used without departing from the present disclosure.

The input shunt resonator 312 is formed by a first inductor 318 and a first capacitor 320 in parallel between an input leg of the π-resistive network and ground. A second capacitor 322 is selectively added in parallel by closing a switch 324 in a high-gain mode. In a low-gain mode, the switch 324 is open, and the second capacitor 322 does not contribute to the input shunt resonator 312 because of the open circuit between the first capacitor 320 and the second capacitor 322.

Similarly, the output shunt resonator 314 is formed by a second inductor 326 and a third capacitor 328 in parallel between an output leg of the π-resistive network and ground. A fourth capacitor 330 is selectively added in parallel by closing a switch 332 in a high-gain mode. In a low-gain mode, the switch 332 is open, and the fourth capacitor 330 does not contribute to the output shunt resonator 314 because of the open circuit between the third capacitor 328 and the fourth capacitor 330.

The series resonator 316 includes a fifth capacitor 334 in series with a third inductor 336 in series with a sixth capacitor 338 between the input node 300 and the output node 302. This places the series resonator 316 in parallel with the resistor 306(1). In a high-gain mode, switches 340(1), 340(2) are closed, adding in a seventh capacitor 342(1) and an eighth capacitor 342(2) in parallel with the capacitors 334, 338, respectively. In a low-gain mode, the switches 340(1), 340(2) are open, and the capacitors 342(1), 342(2) do not contribute to the series resonator 316.

While the above discussion has one way in which the resonating frequency may be selected between modes, it should be appreciated that there may be other ways. For example, if the peak frequency of the resonators needed to be lower for a low-gain mode, then more capacitors would be appropriate in the low-gain mode. In such a situation, it would be appropriate to open switches 324, 332, 340(1), 340(2) in the high-gain mode and close switches 324, 332, 340(1), 340(2) in the low-gain mode. That is, the example of FIG. 3 is presented by way of illustration and is not intended to be limiting.

Note that while the present discussion has focused on merely two modes and two LNAs, it should be appreciated that more modes and more LNAs may be present without departing from the present disclosure. Each mode may have its own attenuation slope correction (i.e., a third mode may have a third attenuation slope correction). The modes may be accommodated by switching in more resistors and capacitors as needed. The position of the dynamic equalizer 108 between the LNAs 104, 106 would not change necessarily if more LNAs are added, but the dynamic equalizer 108 could be positioned serially between any of the LNAs. Likewise, the dynamic equalizer 108 could be positioned serially before the LNAs 104, 106 or serially after the LNAs 104, 106. Practically, given current design constraints, placing the dynamic equalizer 108 before the LNA 104 would have a high noise factor (NF). Likewise, placing the dynamic equalizer 108 after the LNA 106 might negatively impact the IP3 in a high-gain mode. Accordingly, the middle position illustrated remains optimal given current design constraints, but the present disclosure is not limited to this positioning. Further, it should be appreciated that for receiver chains that include more than two LNAs, varied placement of a single equalizer may make more sense. Alternatively, more than one equalizer may be used for optimal operation with equalizers placed in front of, behind, or between LNAs without departing from the present disclosure.

Simulations show that this arrangement provides the desired flatness for the gain response of the receiver chain and is easily implemented in SOI, meeting the size and cost design criteria.

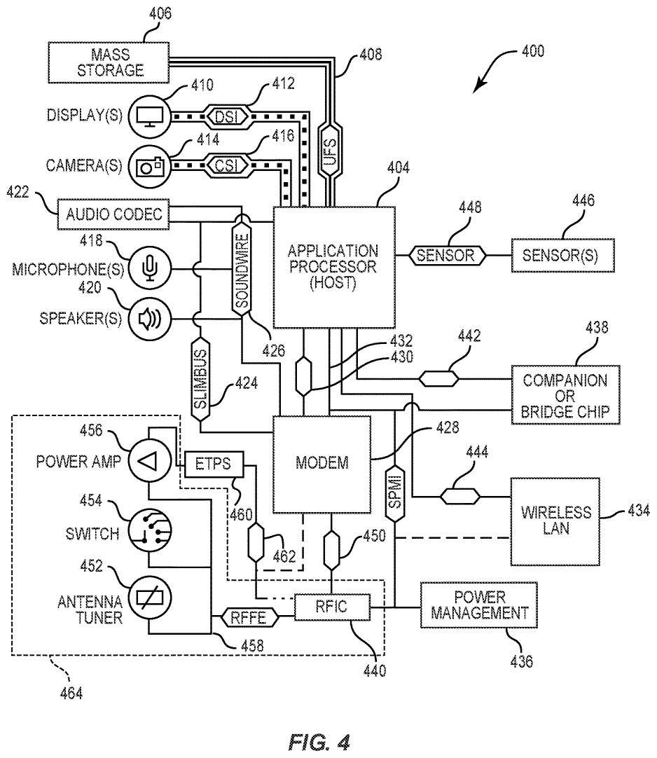

The receiver chain of the present disclosure may be implemented in any number of wireless communication systems, but it is particularly contemplated as being positioned in a base station or a mobile terminal such as a cell phone. In this regard, FIG. 4 is a system-level block diagram of an exemplary mobile terminal 400 such as a smartphone, mobile computing device tablet, or the like. The mobile terminal 400 includes an application processor 404 (sometimes referred to as a host) that communicates with a mass storage element 406 through a universal flash storage (UFS) bus 408. The application processor 404 may further be connected to a display 410 through a display serial interface (DSI) bus 412 and a camera 414 through a camera serial interface (CSI) bus 416. Various audio elements such as a microphone 418, a speaker 420, and an audio codec 422 may be coupled to the application processor 404 through a serial low-power interchip multimedia bus (SLIMbus) 424. Additionally, the audio elements may communicate with each other through a SOUNDWIRE bus 426. A modem 428 may also be coupled to the SLIMbus 424 and/or the SOUNDWIRE bus 426. The modem 428 may further be connected to the application processor 404 through a peripheral component interconnect (PCI) or PCI express (PCIe) bus 430 and/or a system power management interface (SPMI) bus 432.

With continued reference to FIG. 4, the SPMI bus 432 may also be coupled to a local area network (LAN or WLAN) IC (LAN IC or WLAN IC) 434, a power management integrated circuit (PMIC) 436, a companion IC (sometimes referred to as a bridge chip) 438, and a radio frequency IC (RFIC) 440. It should be appreciated that separate PCI buses 442 and 444 may also couple the application processor 404 to the companion IC 438 and the WLAN IC 434. The application processor 404 may further be connected to sensors 446 through a sensor bus 448. The modem 428 and the RFIC 440 may communicate using a bus 450.

With continued reference to FIG. 4, the RFIC 440 may couple to one or more RFFE elements, such as an antenna tuner 452, a switch 454, and a power amplifier 456 through a radio frequency front end (RFFE) bus 458. The switch 454 and/or power amplifier 456 may include the receiver chain of the present disclosure. Additionally, the RFIC 440 may couple to an envelope tracking power supply (ETPS) 460 through a bus 462, and the ETPS 460 may communicate with the power amplifier 456. Collectively, the RFFE elements, including the RFIC 440, may be considered an RFFE system 464. It should be appreciated that the RFFE bus 458 may be formed from a clock line and a data line (not illustrated).

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

1. A receiver chain, comprising:
a first amplifier;
a switch coupled to the first amplifier;
a second amplifier connected in series with the first amplifier through the switch, wherein in a first mode, the switch is closed and the second amplifier is electrically connected to the first amplifier, and wherein in a second mode, the switch is open and the second amplifier is electrically isolated from the first amplifier; and
a reconfigurable gain equalizer serially positioned between the first amplifier and the switch, wherein the reconfiguration gain equalizer compensates for fixed attenuation across frequency that changes based on a mode of operation and variable attenuation that changes based on frequency and mode.

2. The receiver chain of claim 1, wherein the reconfigurable gain equalizer is configured to change an equalization to a first equalization when the second amplifier is in series with the first amplifier or a second equalization when the second amplifier is switched out of a serial path with the first amplifier.

3. The receiver chain of claim 1, further comprising:
an input node configured to be coupled to an antenna path, wherein the first amplifier is coupled to the input node; and
an output node coupled to the second amplifier.

4. The receiver chain of claim 1, wherein the reconfigurable gain equalizer is configured to provide a first attenuation slope correction in a first mode when the second amplifier is in series with the first amplifier and a second attenuation slope correction in a second mode when the second amplifier is switched out of a serial path with the first amplifier.

5. The receiver chain of claim 1, further comprising a bypass circuit comprising a plurality of switches that selectively creates a short circuit bypass around the second amplifier in a first mode and creates an open circuit in a second mode such that the second amplifier is serially coupled to the first amplifier.

6. The receiver chain of claim 1, wherein the reconfigurable gain equalizer comprises a digital step attenuator.

7. The receiver chain of claim 6, wherein the digital step attenuator comprises a π-resistive network.

8. The receiver chain of claim 7, wherein the π-resistive network comprises a first resistor and a second resistor switchably connected in parallel to the first resistor.

9. The receiver chain of claim 1, wherein the reconfigurable gain equalizer comprises an input shunt resonator coupled to the first amplifier.

10. The receiver chain of claim 9, wherein the input shunt resonator comprises an LC circuit comprising an inductor and a capacitor in parallel.

11. The receiver chain of claim 10, wherein the input shunt resonator comprises a second capacitor switchably coupled in parallel to the capacitor.

12. The receiver chain of claim 11, further comprising a switch that connects the second capacitor to the capacitor in a first mode and creates an open circuit between the second capacitor and the capacitor in a second mode.

13. The receiver chain of claim 1, wherein the reconfigurable gain equalizer comprises an output shunt resonator coupled to the second amplifier.

14. The receiver chain of claim 13, wherein the output shunt resonator comprises an LC circuit comprising an inductor and a capacitor in parallel.

15. The receiver chain of claim 14, wherein the output shunt resonator comprises a second capacitor switchably coupled in parallel to the capacitor.

16. The receiver chain of claim 15, further comprising a switch that connects the second capacitor to the capacitor in a first mode and creates an open circuit between the second capacitor and the capacitor in a second mode.

17. The receiver chain of claim 1, wherein the reconfigurable gain equalizer comprises a series resonator coupled to the first amplifier and the second amplifier.

18. The receiver chain of claim 17, wherein the series resonator comprises an LC circuit comprising an inductor serially coupled to a first capacitor and a second capacitor.

19. A method for providing equalization in a receiver chain, comprising:
using a switch to place a first amplifier in series with a second amplifier;
while the second amplifier is in series with the first amplifier, applying a first equalization with a reconfigurable gain equalizer;
using the switch to switch the second amplifier out of series with the first amplifier; and
while the second amplifier is not in series with the first amplifier, applying a second equalization with the reconfigurable gain equalizer, wherein the reconfiguration gain equalizer compensates for fixed attenuation across frequency that changes based on a mode of operation and variable attenuation that changes based on frequency and mode.

20. A wireless computing device comprising:
a transceiver comprising a receiver chain, comprising:
a first amplifier;
a switch coupled to the first amplifier;
a second amplifier connected in series with the first amplifier through the switch, wherein in a first mode, the switch is closed and the second amplifier is electrically connected to the first amplifier, and wherein in a second mode, the switch is open and the second amplifier is electrically isolated from the first amplifier; and
a reconfigurable gain equalizer serially positioned between the first amplifier and the switch, wherein the reconfiguration gain equalizer compensates for fixed attenuation across frequency that changes based on a mode of operation and variable attenuation that changes based on frequency and mode.
